(19) United States
(12) Patent Application Publication
(10) Pub. No.: US 2026/0079198 A1
(43) Pub. Date: Mar. 19, 2026

(54) TESTING CIRCUIT AND TESTING METHOD CAPABLE OF DETECTING CRACKS OF DISPLAY PANEL

(71) Applicant: Novatek Microelectronics Corp., Hsinchu (TW)

(72) Inventor: Chiu-Huang Huang, Hsinchu County (TW)

(73) Assignee: Novatek Microelectronics Corp., Hsinchu (TW)

(21) Appl. No.: 18/885,747

(22) Filed: Sep. 16, 2024

(51) Int. Cl. G01R 31/28

(52) U.S. Cl. CPC G01R 31/2884

(57) ABSTRACT

Testing circuits and testing method are provided. The testing circuit includes a first pad, a second pad, a first test signal generator, a second test signal generator, a switch circuit, and a test signal receiver. The first and second pads are to be respectively coupled across the conductive ring structure. The first test signal generator is coupled to the first pad and configured to provide a first test signal to the first pad. The second test signal generator is coupled to the second pad and configured to provide a second test signal to the second pad. The switch circuit is configured to control the first test signal generator and the second test signal generator to provide the first and second test signals respectively in a first and second modes. The test signal receiver is configured to generate a test result according to a voltage signal received from the first pad.

### BACKGROUND

### 1. Technical Field

The disclosure generally relates to a circuit and a method, and more particularly, to a testing circuit and a testing method capable of detecting cracks of a display panel.

### 2. Description of Related Art

With the miniaturization of a semiconductor device, it becomes important to evaluate whether there are any structural defects or cracks in a specific integrated circuit (IC) or a display panel. More importantly, the evaluation process or evaluation result must meet a certain precision requirement or be resistant to electromagnetic interference (EMI) to a certain level.

### SUMMARY

Accordingly, the disclosure is directed to a testing circuit and a testing method for testing a conductive ring string surrounding a panel with multiple testing modes.

The testing circuit of the present disclosure is configured to test a conductive ring structure. The testing circuit includes a first pad, a second pad, a first test signal generator, a second test signal generator, a switch circuit, and a test signal receiver. The first and second pads are configured to be respectively coupled across the conductive ring structure. The first test signal generator is coupled to the first pad and configured to provide a first test signal to the first pad in a first mode. The second test signal generator is coupled to the second pad and configured to provide a second test signal to the second pad in a second mode. The switch circuit is coupled to the first test signal generator and the second test signal generator. The switch circuit is configured to control the first test signal generator and the second signal generator to respectively provide the first and second test signals in the first and second modes. The test signal receiver is coupled to the first pad. The test signal receiver is configured to generate a test result according to a voltage signal received from the first pad.

The testing method of the present disclosure is configured to test a conductive ring structure. The testing method comprises: providing a first test signal to a first pad coupled to one end of the conductive ring structure to obtain a first test result in a first mode; in response to the first test result being higher than a predetermined value, entering a second mode to provide a second test signal to a second pad coupled to another end of the conductive ring structure to obtain a second test result from the first pad; and determining a structure information of the conductive ring structure according to the first and second test results.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a testing circuit in accordance with some embodiments of the present disclosure.

FIG. 2 illustrates a testing circuit in accordance with some embodiments of the present disclosure.

FIG. 3A illustrates a schematic diagram of the testing circuit operated in the first mode in accordance with some embodiment of the present disclosure.

FIG. 3B illustrates an operating waveform of the testing circuit operated in the first mode in accordance with some embodiments of the present disclosure.

FIG. 4A illustrates a schematic diagram of the testing circuit operated in the second mode in accordance with some embodiment of the present disclosure.

FIG. 4B illustrates an operating waveform of the testing circuit operated in the second mode in accordance with some embodiments of the present disclosure.

FIG. 5 illustrates a flowchart of a testing method in accordance with some embodiments of the present disclosure.

### DESCRIPTION OF THE EMBODIMENTS

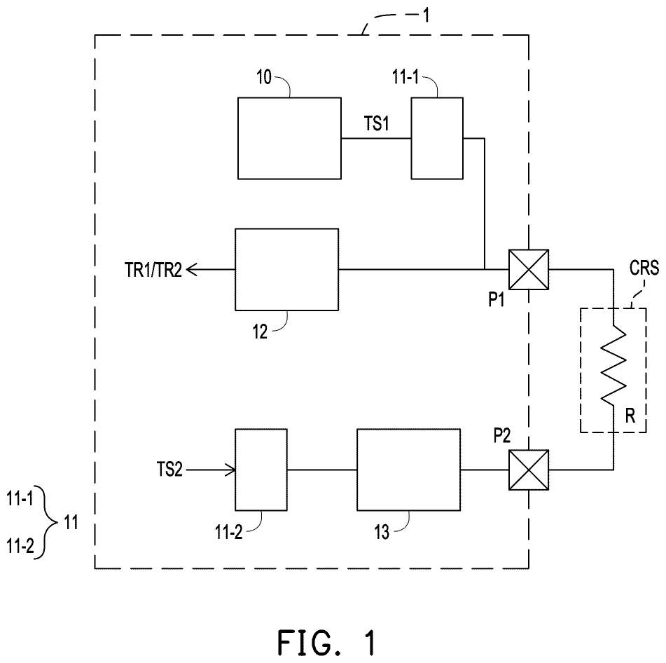

FIG. 1 illustrates a testing circuit 1 in accordance with some embodiments of the present disclosure. The testing circuit 1 may be disposed on a specific integrated circuit (IC) and used to test whether there are any cracks on the IC through testing a conductive ring structure CRS disposed around a border of the IC. In some embodiments, the conductive ring structure is disposed around the border of the panel. A structure integrity of the conductive ring structure CRS may be used as an index of whether there are any structural defects or cracks in the panel. Specifically, the testing circuit 1 may be configured to measure an equivalent resistance R of the conductive ring structure CRS and use the measured resistance R for evaluating whether there are any structure defects on the panel. If the measured resistance R is too high or too low, and is outside of a predetermined resistance range, it probably means that there are defects like short circuits or cracks in the panel.

In this embodiment, the testing circuit 1 includes a first pad P1, a second pad P2, a first test signal generator 10, a switch circuit 11, a test signal receiver 12, and a second test signal generator 13. The first and second pads P1, P2 are used respectively coupled across the conductive ring structure CRS. The first test signal generator 10 is coupled to the first pad P1 through the switch circuit 11 and may be configured to provide a first test signal TS1 to the first pad P1 in a first mode. The second test signal generator 13 is coupled to the second pad P2 and may be configured to provide a second test signal TS2 to the second pad P2 in a second mode. The switch circuit 11 includes a first switch 11-1 and a second switch 11-2, which are respectively coupled to the first test signal generator 10 and the second test signal generator 13. The switch circuit 11 may be configured to control the first test signal generator 10 and the second test signal generator 13 to respectively provide the first and second test signals TS1, TS2 in the first and second modes. The test signal receiver 12 is coupled to the first pad P1. The test signal receiver 12 may be configured to receive a voltage signal from the first pad P1 to generate a test result.

In some embodiments, the first switch 11-1 is coupled between the first test signal generator 10 and the first pad P1. The first switch 11-1 may connect the first test signal generator 10 with the first pad P1, so as to provide the first test signal TS1 to the first pad P1 and further to the conductive ring structure CRS in the first mode. On the other hand, the second switch 11-2 is coupled to an input end of the second test signal generator 13. The second switch 11-2 may be configured to provide the second test signal TS2 to the second test signal generator 13 for further providing the second test signal TS2 to the second pad P2 and the conductive ring structure CRS. Specifically, the first mode and the second mode are different testing modes capable of measuring the resistance R of the conducive ring structure CRS with different precisions and various immunities to EMI. With the switch circuit 11, the test circuit 1 may be realized to perform flexible testing modes to the conductive ring structure CRS, adapting in requirements for different testing environments and EMI immunities.

In brief, the testing circuit 1 may be operated in the first mode or the second mode for measuring the resistance of the conductive ring structure CRS with different precisions. In the first mode, the testing circuit 1 may use the first test signal generator 10 to provide the first test signal TS1 for the test signal receiver 12 to receive a first voltage signal from the first pad P1 and generate a first test result TR1 with a higher precision. In the second mode, the testing circuit 1 may use the second test signal generator 13 to provide the second test signal TS2 to the second pad P2 for the test signal receiver 12 to receive a second voltage signal from the first pad P1 and generate a second test result TR2 with a better electromagnetic susceptibility (EMS). Therefore, the testing circuit 1 may be operated in the first or second mode for measuring the resistance of the conductive ring structure CRS either higher precision or with better EMS.

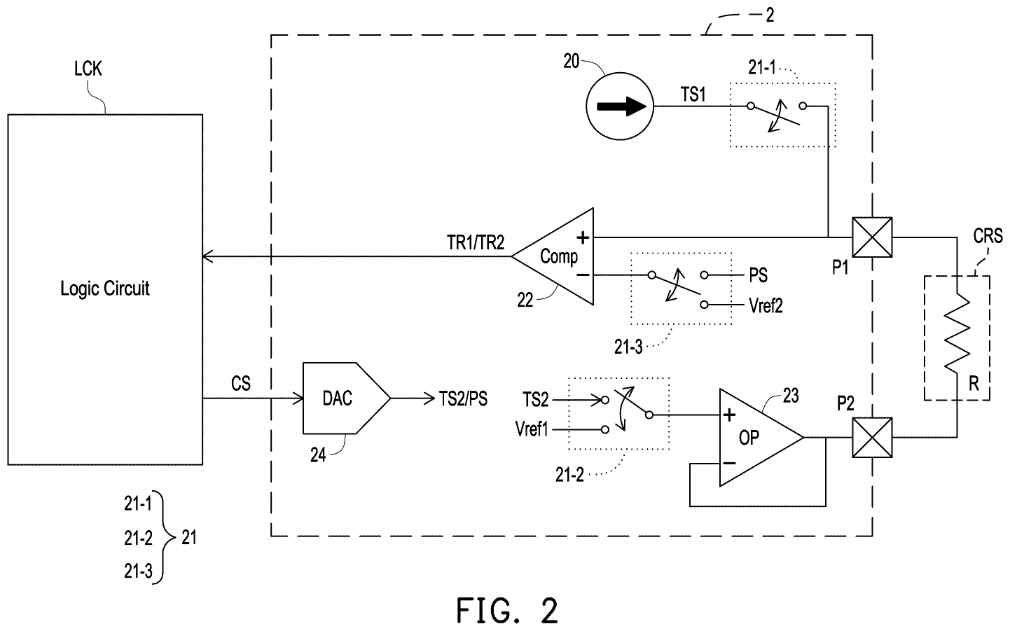

FIG. 2 illustrates a testing circuit 2 in accordance with some embodiments of the present disclosure. The testing circuit 2 in FIG. 2 is similar to the testing circuit 1 in FIG. 1, so the same labels are used to denote similar components in FIGS. 1, 2.

In this embodiment, the testing circuit 2 is further coupled to a logic circuit LCK. The logic circuit LCK may be configured to provide a control signal CS to the testing circuit 2 for instructing the testing circuit 2 to generate the first and second test signals TS1, TS2. Specifically, the testing circuit 2 includes a first pad P1, a second pad P2, a first test signal generator 20, a switch circuit 21, a test signal receiver 22, a second test signal generator 23, a digital-to-analog converter (DAC) 24.

In this embodiment, the first test signal generator 20 is a current source and the provided first test signal TS1 is a current test signal. The first test signal generator 20 may be configured to provide the first test signal TS1 to the conductive ring structure CRS. The test signal receiver 22 may be configured to receive a first voltage signal corresponding to the resistance R of the conductive ring structure CRS from the first pad P1. The test signal receiver 22 may be configured to generate a first test result TR1 by comparing the first voltage signal with a proximation signal to evaluate and proximate a level of the resistance R. Details regarding the comparison will be described in greater details in the following, which are omitted herein. Specifically, in the first mode, the first switch 21-1 coupled between the first test signal generator 20 and the first pad P1 may be configured to connect the first test signal generator 20 to the first pad P1, so as to provide the first test signal TS1 to the first pad P1. In the second mode, the first switch 21-1 may be configured to disconnect the first test signal generator 20 from the first pad P1 to isolate the first test signal generator 20 from the testing in the second mode. In this way, the first switch 21-1 may be used to realize selective signal transmission from the first test signal generator 20 to the first pad P1 in different modes.

In this embodiment, the second test signal generator 23 is an operational amplifier (OP). The second test signal generator 23 has a first input end (i.e., a positive input end), a second input end (i.e., a negative input end), and an output end coupled to the second input end. The OP may be coupled to function as a unit gain buffer for buffering out signal received from a positive input end. In the first mode, the second switch 21-2 is switched to provide a known first reference voltage Vref1 (e.g., a ground voltage) to the second pad P2, so that the test signal receiver 22 may accordingly analyze the cross voltage of the conductive ring structure CRS based on the known first reference voltage Vref1. In the second mode, the second test signal generator 23 may be configured to provide a pulse signal as the second test signal TS2 for measuring the resistance R of the conductive ring structure CRS. Specifically, in the second mode, the second switch 21-2 is switched to provide the second test signal TS2 to the first input end of the second test signal generator 23, so the second test signal TS2 may be buffered out to the second pad P2 and the conductive ring structure CRS by the second test signal generator 23. The pulse signal of the second test signal TS2 will travel through the conductive ring structure CRS and received by the test signal receiver 22, so the second voltage signal may be used to obtain a R-C time constant information related to the resistance R.

In addition to the first switch 21-1 and the second switch 21-2, the switch circuit 21 further includes a third switch 21-3 coupled to the second input end (i.e., a negative input end) of the test signal receiver 22. The third switch 21-3 is switched to respectively provide the proximation signal PS and the second reference voltage Vref2 as a reference signal to the test signal receiver 22 in the first and second modes.

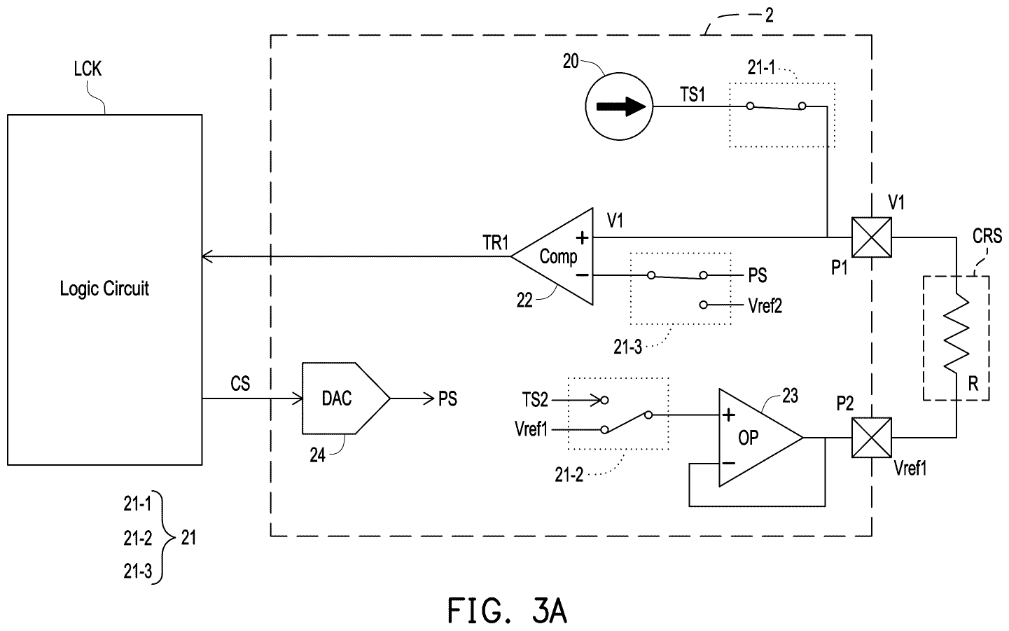

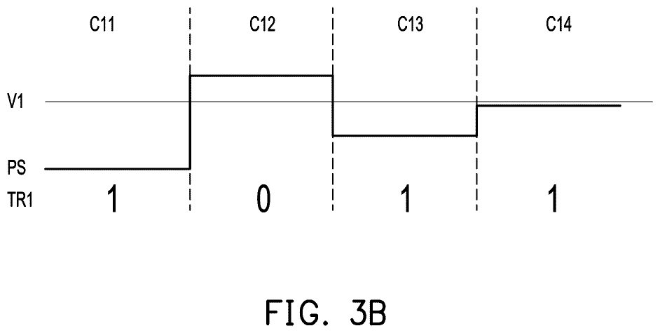

FIG. 3A illustrates a schematic diagram of the testing circuit 2 operated in the first mode in accordance with some embodiment of the present disclosure.

In this embodiment, the testing circuit 2 is operated in the first mode, and the first test signal generator 20 is coupled by the first switch 21-1 to the first pad P1 for providing the first test signal TS1 to the first pad P1. The second switch 21-2 is switched to provide the first reference voltage Vref1 to the first input end (i.e., the positive input end) of the second test signal generator 23. The third switch 21-3 is switched to provide the proximation signal PS to the second input end (i.e., the negative input end) of the test signal receiver 22.

In operation of the first mode, the first test signal TS1 provided to the first pad P1 is a current signal. The fixed first reference voltage Vref1 is provided to the second pad P2. To accurately obtain the level of the first voltage signal V1 corresponding to the resistance R1, the logic circuit LCK is configured to provide the digital control signal CS, which is transformed as the proximation signal PS through the DAC 24, to approximate the level of the first voltage signal V1. Specifically, the digital value of the control signal CS is transformed into an analog voltage level as the proximation signal PS by the DAC 24. The test signal receiver 22 is configured to compare the first voltage V1 with the proximation signal PS to generate one bit of the first test result TR1. The logic circuit LCK receiving the first test result TR1 may be configured to adjust the digital value of the control signal CS to make the proximation signal PS approaching the first voltage signal V1. In some embodiments, the overall approaching process of the proximation signal PS to the first voltage signal V1 may follow a binary search algorithm, and the test signal receiver 22, the logic circuit LCK, and the DAC 24 may together function as a successive approximation analog-to-digital converter (SAR ADC). In this way, all bits of the generated first test results TR1 may be used to approximate the first voltage signal V1 and the cross voltage of the resistance R, since the first voltage signal V1 is in a linear relationship to the resistance R.

FIG. 3B illustrates an operating waveform of the testing circuit 2 operated in the first mode in accordance with some embodiments of the present disclosure.

In FIG. 3B, two lines respectively corresponding to waveforms of the first voltage V1 and the proximation signal PS are illustrated. In a first comparison cycle C11, the proximation signal PS may be set at a voltage level between logic 0 and 1 by the logic circuit LCK. Based on the first voltage signal V1 being greater than the proximation signal PS, the test signal receiver 22 may be configured to generate a first bit of the first test result TR1 with the digital value 1. In a second comparison cycle C12, based on the first test result TR1 in the first comparison cycle C11, the logic circuit LCK may be configured to set the proximation signal at a voltage level between logic 10 and 11, so the test signal receiver 22 may be configured to compare the first voltage V1 with the proximation signal PS to generate the second bit of the first test result TR1 with the digital value 0. The proximation and comparison process repeats iteratively in the following comparison cycles C13, C14, and so on (if necessary). As a result, the first voltage signal V1 may be approximated by the first test result TR1 of 1011, which can be used to analyze whether the resistance R of the conductive ring structure CRS is within or outside of the predetermined resistance range.

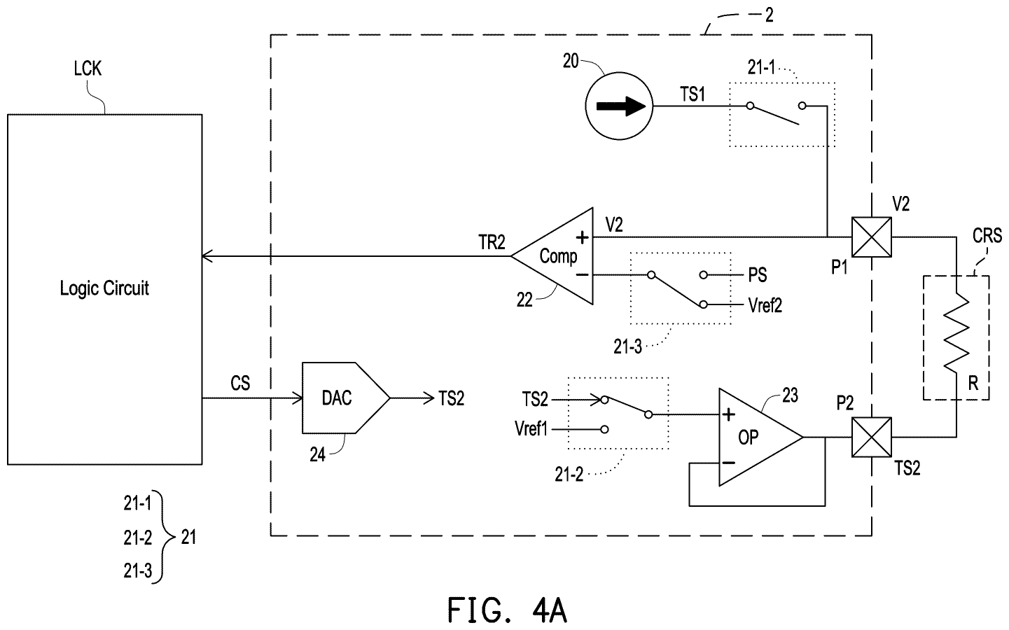

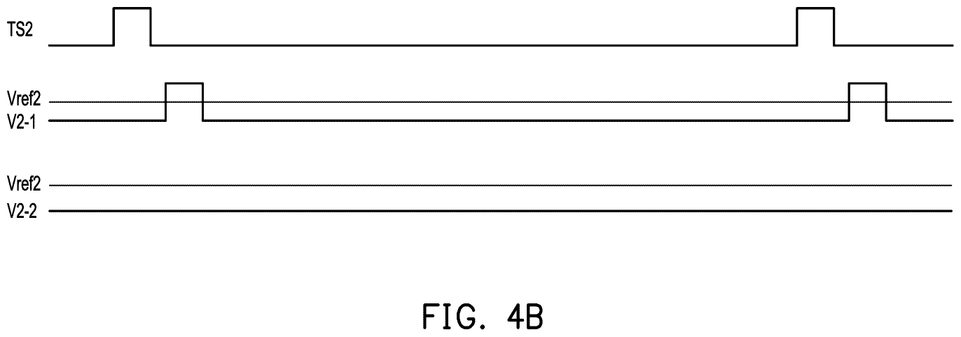

FIG. 4A illustrates a schematic diagram of the testing circuit 2 operated in the second mode in accordance with some embodiment of the present disclosure.

In this embodiment, the testing circuit 2 is operated in the second mode, so the first test signal generator 20 is disconnected from the first pad P1 by the first switch 21-1. The second switch 21-2 is switched to provide the second test signal TS2 to the first input end (i.e., the positive input end) of the second test signal generator 23. The third switch 21-3 is coupled to provide the second reference voltage Vref2 to the second input end (i.e., the negative input end) of the test signal receiver 22.

In the second mode, the second test signal TS2 provided to second test signal generator 23 is a pulse signal. The second test signal TS2 may be generated through converting the control signal CS from digital value to an analog voltage by the DAC 24. Further, the test signal receiver 22 is configured to receive the second voltage V2 from the first pad P1 corresponding to the second test signal TS2 attenuated by the conductive ring structure CRS. A time constant constructed by the equivalent resistance R and capacitance of the conductive ring structure CRS may be obtained from a delay and/or a voltage drop between the second test signal TS2 and the second voltage signal V2. The test signal receiver 22 may be configured to generate the second test result TR2 showing whether the second test signal TS2 is received within a predetermined time range by comparing the second voltage signal V2 with the second reference voltage Vref2.

FIG. 4B illustrates an operating waveform of the testing circuit 2 operated in the second mode in accordance with some embodiments of the present disclosure.

The first row of FIG. 4B illustrates a waveform of the test signal TS2 provided to the second pad P2. The second row of FIG. 4B illustrates a waveform of a second voltage V2-1. Specifically, the test signal receiver 22 may be configured to compare the second voltage V2-1 with second reference voltage Vref2 to generate the second test result TR2. Therefore, the logic circuit LCK may be configured to evaluate whether the conductive ring structure CRS is defected or cracked based on the delay of the second test signal TS2. If the delay between the second test signal TS2 and the second voltage signal V2 is within a predetermined time range, the logic circuit LCK may accordingly determine that the conductive ring structure CRS is good and intact. Otherwise, if the delay between the second test signal TS2 is too long or the received pulse amplitude is too low, the logic circuit LCK may accordingly determine that the conductive ring structure CRS is defected.

The third row of FIG. 4B illustrates a waveform of a second voltage V2-2. As can be seen, the second voltage level V2-2 is lower than the second reference volage Vref2. In this embodiment, the second voltage signal V2-2 is kept lower than the second reference voltage Vref2, so the logic circuit LCK may accordingly determine that the conductive ring structure CRS is defected or damaged.

Each of the testing circuits 1, 2 may be applied to various electronic devices with different precision requirements. For example, the testing circuits 1, 2 may be operated in the first mode to test the structure integrity of a panel in mobile devices, PCs, etc. with higher accuracy. In some examples, the testing circuits 1, 2 may be operated in the second mode to test the structure integrity of a panel applied in automobiles, etc. which are more vulnerable or sensitive to EMI. In some embodiments, the testing circuits 1, 2 may be operated in both modes to test the structure integrity of the panel applied in automobiles, etc. Therefore, the testing circuits 1, 2 may be used to test whether there are any cracks or defects on the panel while ensuring that relevant EMI/EMS requirements can be followed.

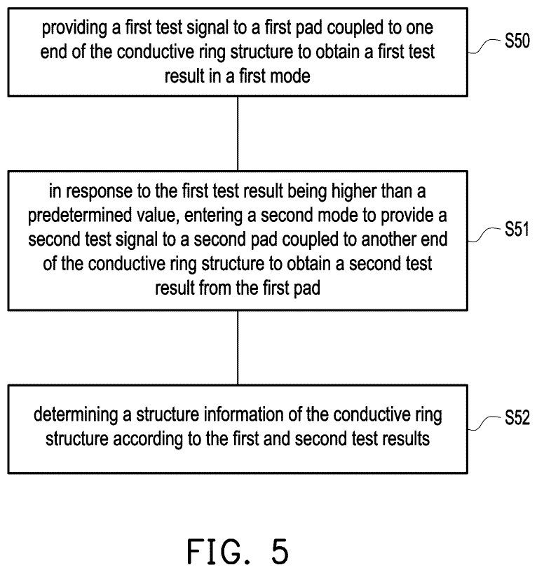

FIG. 5 illustrates a flowchart of a testing method in accordance with some embodiments of the present disclosure. The testing method may be executed by either one of the testing circuits 1, 2 to test the conductive ring structure CRS.

The testing method includes steps S50-S52. In step S50, a first test signal TS1 is provided to a first pad P1 coupled to one end of the conductive ring structure CRS to obtain a first test result TR1 in a first mode. In step S51, in response to the first test result TR1 being higher than a predetermined value, a second mode is entered to provide a second test signal TS2 to a second pad P2 coupled to another end of the conductive ring structure CRS to obtain a second test result TR2 from the first pad P1. In step S52, a structure information of the conductive ring structure is determined according to the first and second test results TR1, TR2.

Specifically, the testing method may control the testing circuit 1/2 operated in the first mode first to perform a more accurate test to the conductive ring structure CRS. Since the testing performed by the testing circuit 1/2 in the first mode is more vulnerable to EMI, the testing circuit 1/2 may be configured to be operated in the second mode to perform another testing when the first test result TR1 shows that the conductive ring structure is defected. Specifically, when the first test result TR1 is higher than the predetermined value (i.e., the first voltage signal V1 is higher than a predetermined voltage level), showing that the equivalent resistance R may be too high and suggesting that the conductive ring structure CRS may be damaged, the testing method may control the testing circuit 1/2 to be operated in the second mode to see whether the first test result TR1 is correct. In the second mode, when the second voltage signal V2 received from the first pad P1 is lower than the second reference voltage Vref2 in the predetermined time range, the first test result TR1 may be verified and the conductive ring structure CRS may be damaged. Otherwise, when the second voltage signal V2 received from the first pad P1 is higher than the second reference voltage Vref2 in the predetermined time range, contradicting to the first test result TR1, the structure information may be determined that the conductive ring structure CRS is still intact and testing performed in the first mode may be affected by EMI.

Therefore, with the testing method controlling the testing circuit 1/2 in a way combining the first and second modes, the testing circuit 1/2 may also be adapted to perform testing in the first mode, and selectively perform the second mode for verification. In this way, the testing circuit may be controlled by the testing method to be applied in an EMS sensitive environment to obtain the high precision testing result but also with a better immunity to EMI.

In summary, the testing circuit and the testing method may be applied in a panel for determining a structure integrity of the conductive ring structure, to further determine whether the panel is safe and intact. The testing circuit is equipped with circuits operable to be switched between the first and second modes, so as to provide options to different testing modes. In this way, the testing circuit may be applied to the ICs with different EMI/EMS requirements, improving the adaptability of the testing circuit.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A testing circuit configured to test a conductive ring structure, the testing circuit comprising:
a first pad and a second pad configured to be respectively coupled across the conductive ring structure;
a first test signal generator coupled to the first pad and configured to provide a first test signal to the first pad in a first mode;
a second test signal generator coupled to the second pad and configured to provide a second test signal to the second pad in a second mode;
a switch circuit coupled to the first test signal generator and the second test signal generator, the switch circuit being configured to control the first test signal generator and the second test signal generator to respectively provide the first and second test signals in the first and second modes; and
a test signal receiver coupled to the first pad, the test signal receiver being configured to generate a test result according to a voltage signal received from the first pad.

2. The testing circuit of claim 1, wherein the first test signal generator comprises a current source configured to generate a current test signal as the first test signal.

3. The testing circuit of claim 2, wherein in the first mode, the first test signal generator is configured to provide the current test signal to the first pad, and the test signal receiver is configured to receive the voltage signal from the first pad for generating the test result.

4. The testing circuit of claim 1, wherein the second test signal generator comprises an operational amplifier (OP), the OP has a first input end, a second input end, and an output end coupled to the second input end and the second pad.

5. The testing circuit of claim 4, wherein the second test signal is a pulse signal, and in the second mode, the second test signal is provided to the first input end of the second test signal generator, and the second test signal generator is configured to buffer out the second test signal to the second pad.

6. The testing circuit of claim 1, wherein the test signal receiver comprises a comparator, the comparator has a first input end coupled to the first pad, a second input end, and an output end, the test signal receiver is configured to compare the voltage signal received from the first input end with a reference signal received from the second input end to generate the test result at the output end.

7. The testing circuit of claim 6, wherein the switch circuit comprises a first switch coupled between the first test signal generator and the first pad, the first switch being switched to connect the first test signal generator to the first pad in the first mode for provide the first test signal to the first pad, and switched disconnect the first test signal generator from the first pad in the second mode.

8. The testing circuit of claim 7, further comprising:
a second switch coupled to a first input end of the second test signal generator, wherein in the first mode, the second switch is switched to provide a first reference voltage to the first input end of the second test signal generator; and
a third switch coupled to the second input end of the test signal receiver, wherein in the first mode, the third switch is switched to provide a proximation signal to the second input end of the test signal receiver.

9. The testing circuit of claim 8, wherein in the second mode, the second switch is switched to provide the second test signal to the first input end of the second test signal generator, and
wherein in the second mode, the third switch is switched to provide a second reference voltage to the second input end of the test signal receiver.

10. The testing circuit of claim 8, further comprising:
a digital-to-analog converter (DAC) coupled to the second and third switch, the DAC being configured to provide the proximation signal to the third switch in the first mode, and provide the second test signal to the second switch in the second mode according to a control signal.

11. A testing method configured to test a conductive ring structure, the testing method comprising:
providing a first test signal to a first pad coupled to one end of the conductive ring structure to obtain a first test result in a first mode;
in response to the first test result being higher than a predetermined value, entering a second mode to provide a second test signal to a second pad coupled to another end of the conductive ring structure to obtain a second test result from the first pad; and
determining a structure information of the conductive ring structure according to the first and second test results.

12. The testing method of claim 11, wherein the first test signal is a current signal, and obtaining the first test result in the first mode comprises:
receiving a first voltage signal from the first pad; and
comparing the first voltage signal with a first reference voltage to generate the first test result.

13. The testing method of claim 11, wherein the second test signal is a pulse signal, and providing the second test signal in the second mode comprises:
receiving a second voltage signal from the first pad; and
in a predetermined time range, comparing the second voltage signal with a second reference voltage to generate the second test result.
